(19) United States
(12) Patent Application Publication
(10) Pub. No.: US 2011/0109781 A1
(43) Pub. Date: May 12, 2011

(54) SOLID STATE IMAGING DEVICE AND METHOD OF CONTROLLING THE SAME

(76) Inventor: Maki SATO, Yamato-shi (JP)

(21) Appl. No.: 12/939,612

(22) Filed: Nov. 4, 2010

(30) Foreign Application Priority Data
Nov. 9, 2009 (JP) 2009-256572

(51) Int. Cl. H04N 5/335; H01L 31/102; H01L 27/146

(52) U.S. Cl. 348/308; 250/214 R; 250/208.1; 348/E05.091

(57) ABSTRACT

According to one embodiment, a solid state imaging device includes a first photodiode, a first transistor, a floating diffusion, a second transistor, a third transistor. The first photodiode performs photoelectric conversion and accumulates a charge obtained. The first transistor reads the charge. The floating diffusion is one end of a current pathway of the first transistor. The charge is read through the first transistor to the first node. The second transistor's gate is connected to the first node. The second transistor's one end of a current pathway is connected to a vertical signal line. The one end of a current pathway of the third transistor is connected to the floating diffusion. Another end is connected to a power supply. The charge accumulated in the floating diffusion is discharged to the power supply by turning on the third transistor.

### CROSS-REFERENCE TO RELATED APPLICATIONS

This application is based upon and claims the benefit of priority from Japanese Patent Application No. 2009-256572, filed Nov. 9, 2009; the entire contents of which are incorporated herein by reference.

### FIELD

Embodiments described herein relate generally to a solid state imaging device and a method of controlling the same, for example.

### BACKGROUND

In a solid state imaging device, a plurality of pixels arranged in a matrix fashion are formed in a pixel unit. A plurality of pixels are connected in common to a vertical signal line. A pixel signal is read from a pixel arranged on a selected row through the vertical signal line.

As a pixel structure of a CMOS sensor, there are a structure in which a selection transistor is provided in a unit pixel cell and a structure in which the selection transistor is omitted.

Jpn. Pat. Appin. KOKAI Publication No. 2004-320592 discloses to select a row using potential control of not the selection transistor but floating diffusion (floating diffusion layer of pixel unit) in a case of the structure without the selection transistor.

In a case of the structure with the selection transistor, it is not required to consider of the floating diffusion in a non-selected row.

However, in a case of the structure in which the selection transistor is omitted, a magnitude of the pixel signal read from the pixel of the selected row is limited to the potential of the floating diffusion at a non-selected time. Therefore, a dynamic range of the floating diffusion becomes narrower as compared to the case of the structure in which the selection transistor is provided.

Also, variation in the potential of the vertical signal line when reading the reset potential of the selected row is transmitted to the floating diffusion of the non-selected row including the shutter row by coupling. Therefore, the dynamic range of the pixel signal of the floating diffusion of the selected row becomes further narrower. Therefore, it is desirable to make the dynamic range large.

### BRIEF DESCRIPTION OF THE DRAWINGS

FIG. 1 is a block diagram of a solid state imaging device according to a first embodiment;

FIG. 2 is a block diagram of a sensor core unit of the solid state imaging device according to the first embodiment;

FIGS. 3A and 3B are views illustrating a method of reading the solid state imaging device according to the first embodiment;

FIG. 4 is a time chart of the method of reading the solid state imaging device according to the first embodiment; and

FIG. 5 is a time chart of a method of reading a solid state imaging device according to a second embodiment.

### DETAILED DESCRIPTION

Hereinafter, first and second embodiments are described with reference to the drawings. In this description, common reference numerals are given to common parts throughout the drawings.

In general, according to one embodiment, a solid state imaging device includes a solid state imaging device includes a photodiode, a first transistor, a floating diffusion, a second transistor, and a third transistor. The photodiode performs photoelectric conversion of received light and accumulates a charge obtained by the photoelectric conversion. The first transistor reads the charge accumulated in the photodiode. The floating diffusion is one end of a current pathway of the first transistor, and the charge is read to the floating diffusion through the first transistor. The second transistor's gate is connected to the floating diffusion. One end of a current pathway of the second transistor is connected to a vertical signal line. One end of a current pathway of the third transistor is connected to the floating diffusion. Another end of a current pathway of the third transistor is connected to a power supply. The charge accumulated in the floating diffusion is discharged to the power supply by turning on the third transistor.

### First Embodiment

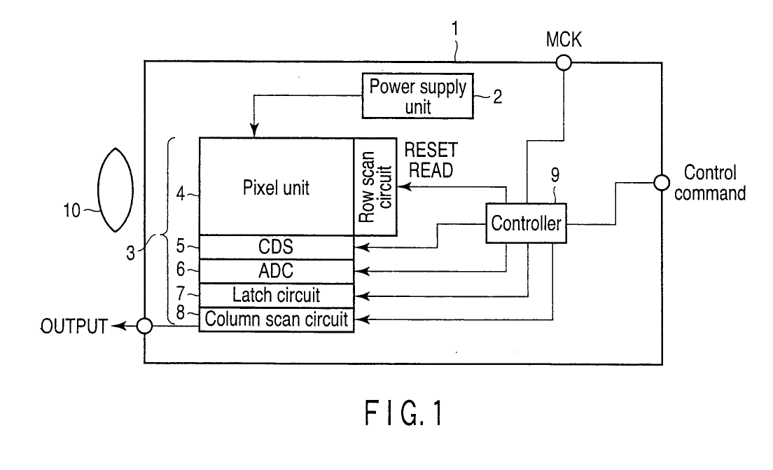

The solid state imaging device and a method of controlling the same according to the first embodiment are described with reference to FIG. 1. FIG. 1 illustrates a configuration example of the solid state imaging device according to the first embodiment. A selected row indicates a row in which read of the charge is performed 1, and a shutter row indicates a row in which a shutter operation is performed.

### <Entire Configuration>

As illustrated in FIG. 1, a solid state imaging device 1 comprises a power supply unit 2, a sensor core unit 3, a controller 9, and a lens 10. The sensor core unit 3 comprises a pixel unit 4, a noise cancel circuit 5 (hereinafter, referred to as a CDS 5), an AD conversion circuit 6 (hereinafter, referred to as an ADC unit 6), a latch circuit 7, and a horizontal shift register 8. Hereinafter, each unit is described in detail.

The power supply unit 2 generates a plurality of predetermined voltages and applies a plurality of generated voltages to the sensor core unit 3 including the pixel unit 4. Especially, when applying the voltage to the pixel unit 4, the power supply unit 2 generates any one of a voltage VDD_{H} (internal voltage), a voltage VDD_{L}, and a voltage VDD_{(L-α)}. Herein, it is represented as voltage VDD_{H}>voltage VDD_{L}>voltage VDD_{(L-α)}. The voltage VDD_{(L-α)} is set to either of zero potential or a negative voltage. That is, the power supply unit 2 comprises an internal voltage generator which generates the voltage VDD_{H} and a negative voltage generator.

When the voltage VDD_{(L-α)} is set to negative voltage, the voltage VDD_{(L-α)} is generated by the negative voltage generator. Also, when the voltage VDD_{(L-α)} is set to the zero potential, it is only necessary to electrically ground an output end in the power supply unit 2.

Further, when generating the voltage VDD_{L}, the voltage VDD_{L} may be generated by decreasing the voltage from the voltage VDD_{H} by an amount corresponding to a resistive element using the resistive element (not illustrated) provided inside the power supply unit 2.

The voltages VDD_{H}, VDD_{L}, and VDD_{(L-α)} are output to the pixel unit 4 at a predetermined timing by the controller 9.

The sensor core unit 3 comprises a plurality of pixels (hereinafter, referred to as pixels) arranged in a matrix fashion. That is, in the pixel unit 4, the shutter operation and read operation (reset operation and read operation of a video signal) for a plurality of arranged pixels are performed based on a signal RESET and a signal READ supplied from the controller 9.

Herein, the shutter operation is an operation to discard once the video signal (voltage obtained by a photoelectric effect) held by the pixel before reading the video signal from the pixel after the reset operation.

The CDS 5 cancels noise included in the video signal read from the pixel unit 4. Specifically, the CDS 5 samples a reset voltage, to be described later, read from the pixel. Thereafter, the CDS 5 samples a pixel voltage corresponding to the video signal read from the pixel. A difference between the reset voltage and the pixel voltage which are sampled is obtained. In this manner, the video signal from which fixed pattern noise due to threshold variation of a transistor Tb and the like is removed may be obtained.

The ADC unit 6 performs A/D (Analog-to-Digital) conversion for the video signal of which noise is cancelled by the above-described CDS 5 to obtain a 10-bit digital signal, for example. The latch circuit 7 latches the digital signal obtained by the ADC unit 6.

The horizontal shift register 8 gives instructions to read the digital signal latched by the latch circuit 7.

The controller 9 controls a timing of the solid state imaging device 1 based on a clock signal given by a master clock MCK. The master clock MCK is the clock signal obtained based on a clock (hereinafter, referred to as an external clock), for example, provided outside the solid state imaging device 1. Also, the controller 9 receives a control command from externally to allow a system of the entire solid state imaging device 1 to operate.

The control command is an operation mode of a camera (night-view mode and high-speed mode) and the like, for example.

The controller 9 applies the RESET signal and the READ signal, for example, out of the commands received from outside to the pixel unit 4. Also, as described above, the controller 9 controls a magnitude of the predetermined voltage applied to the pixel unit 4 and a timing to apply the voltage of the power supply unit 2, thereby generating a horizontal synchronization signal XHS applied once per row (to be described later). One horizontal period for the pixel unit 4 is set by the signal XHS.

The lens 10 receives light from outside and supplies the received light to the pixel unit 4 after allowing the same to pass through a break filter. The filter breaks the light into RGB components.

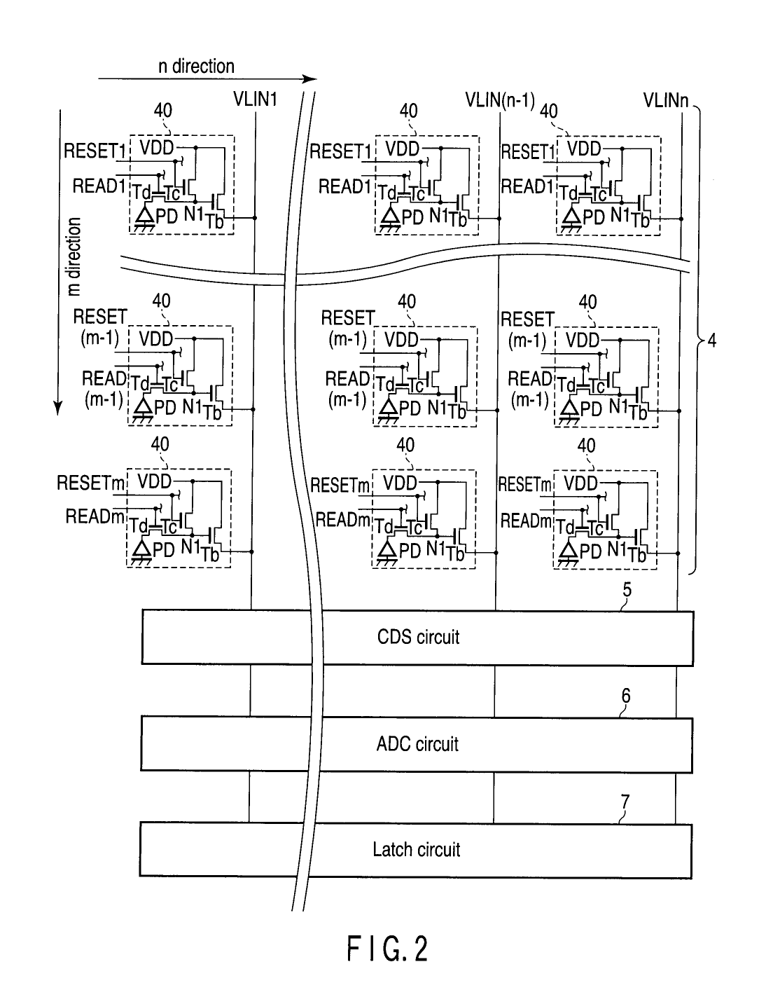

Next, the pixel unit 4 in the above-described sensor core unit 3 is described in detail with reference to FIG. 2. FIG. 2 is a block diagram of the sensor core unit 3.

### <Regarding Detail of Pixel Unit 4>

As illustrated in FIG. 2, in the pixel unit 4, m pixels 40 installed in a vertical direction and connected to each of n vertical signal lines VLIN (n and m are natural numbers) are arranged. That is, the pixel unit 4 comprises nxm pixels 40 arranged in the matrix fashion. The CDS circuit 5, the ADC circuit 6 and the latch circuit 7 are connected to each vertical signal line VLIN. Hereinafter, description focuses on the pixel 40 arranged on a vertical signal line VLIN1 and a first line in a horizontal direction orthogonal to the vertical signal line VLIN.

The pixel 40 comprises MOS transistors Tb, Tc and Td, and a photodiode PD. A signal RESET1 applied from the controller 9 is applied to a gate of the MOS transistor Tc.

Any one of the internal voltage VDD_{H} (for example, 2.5 V), the voltage VDD_{L}, and the voltage VDD_{(L-α)} (simply represented as VDD in the drawing) is supplied from the power supply unit 2 through a pixel power supply PXVDD (represented as VDD in the drawing, hereinafter, also simply referred to as a pixel power supply) to a drain end of the MOS transistor Tc.

A source end of the MOS transistor To is connected to a connection node N1 (floating diffusion). That is, the MOS transistor Tc serves as a reset transistor which generates the reset voltage which becomes a reference voltage of the video signal read from the photodiode PD.

A signal READ1 supplied from the controller 9 is applied to a gate of the MOS transistor Td, a drain end thereof is connected to the node N1, and a cathode of the photodiode PD is connected to a source end thereof. That is, the MOS transistor Td serves as the transistor for read of a signal charge.

Also, an anode of the photodiode PD is grounded.

The connection node N1 is connected to a gate of the MOS transistor Tb. Any one of the internal voltage VDD_{H}, the voltage VDD_{L}, and the voltage VDD_{(L-α)} is supplied from the pixel power supply PXVDD to a drain end of the MOS transistor Tb. The vertical signal line VLIN1 is connected to a source end of the MOS transistor Tb. The MOS transistor Tb serves as the transistor for amplification which amplifies the pixel signal (reset signal and video signal). The gate of the MOS transistor Tb, the source end of the MOS transistor Tc, and the drain end of the MOS transistor Tb are connected in common to the connection node N1.

The node N1 is the node which detects the potential.

Also, the signal line which transmits the signal RESET1 and the signal READ1 are connected in common to the pixels 40 arranged on the first line in the horizontal direction orthogonal to the vertical signal line VLIN. That is, the signal line is connected in common to the pixels 40 connected to the first line in the horizontal direction orthogonal to the vertical signal line VLIN and each of the vertical signal lines VLIN1 to VLINn.

This is similar in second to mth lines in the horizontal direction orthogonal to the vertical signal line VLIN. Also, the pixel power supply PXVDD is connected in common to all of n pixels 40 arranged on each of the first to mth lines.

Also, the above-described pixels 40 arranged on the same column are connected in common to any one of the vertical signal lines VLIN1 to VLINn through the source end of the MOS transistor Tb.

Hereinafter, when the vertical signal lines VLIN1 to VLINn are not distinguished from one another, they are simply referred to as the vertical signal line VLIN.

Also, any one of the signals RESET1 to RESETm and any one of the signals READ1 to READm are applied in common to the pixels 40 on the same row. Hereinafter, when the signals RESET1 to RESETm and the signals READ1 to READm are also not distinguished from one another, they are simply referred to as the signal RESET and the signal READ.

### <Regarding Operation of Pixel Unit 4>

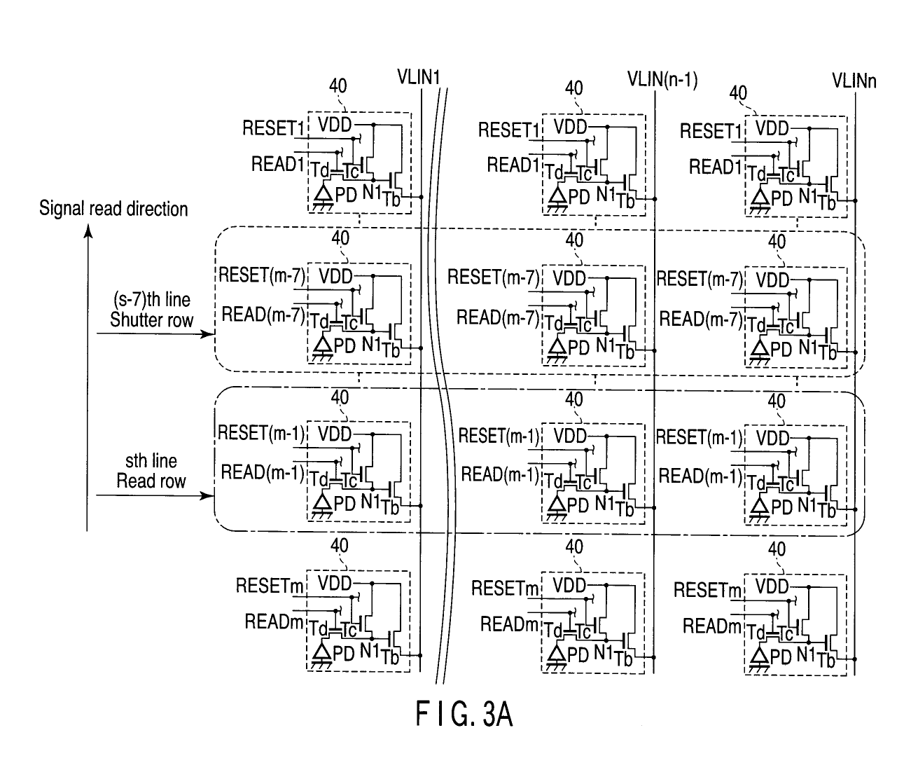

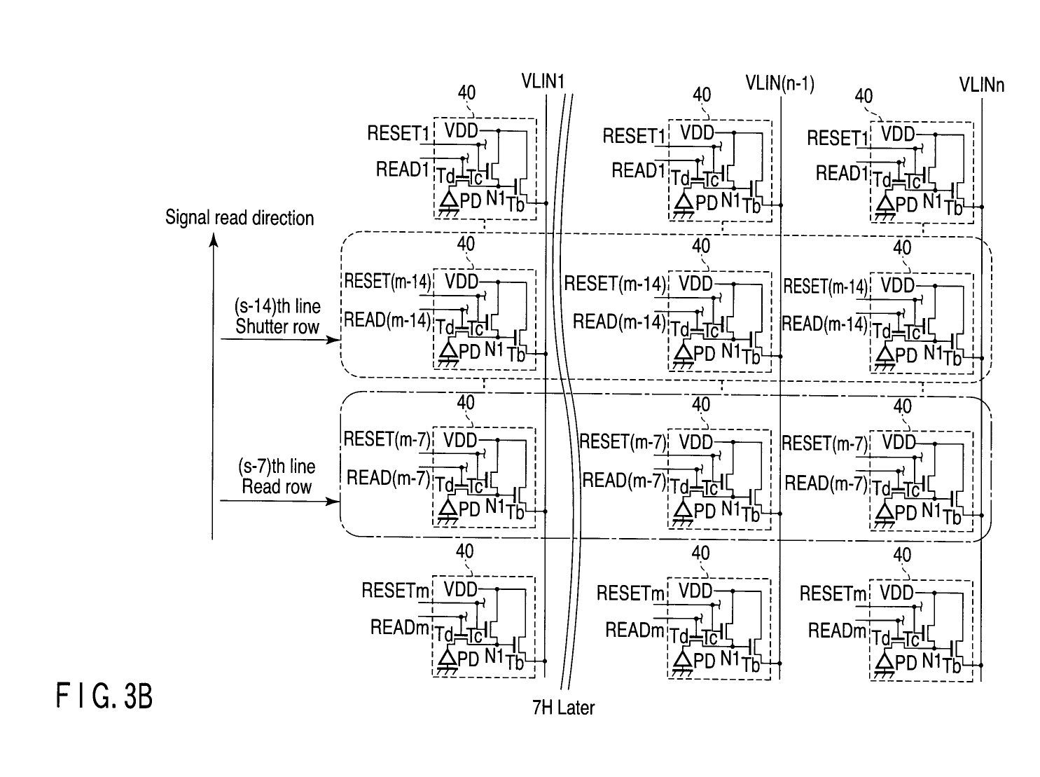

Next, an operation when reading a voltage corresponding to the light incident from the lens 10 from the pixel 40 to the vertical signal line VLIN (method of reading the solid state imaging device comprising a rolling shutter) is described with reference to FIGS. 3A and 3B. FIG. 3A illustrates selected positions of the pixels 40 on a (s-7)th row and a sth row at a certain time. FIG. 3B illustrates the selected positions of the pixels 40 on a (s-14)th row and the (s-7)th row after seven horizontal periods (7H) have passed from the state illustrated in FIG. 3A, for example (s is a natural number).

As described above, the solid state imaging device according to this embodiment has a function referred to as the rolling shutter. That is, the reset signal and the video signal are read from the pixels 40 on the selected row out of m rows. Thereafter, before executing sampling, the pixels 40 of m rows are sequentially selected. In this manner, an operation to eliminated the charge accumulated in the photodiode PD in the selected pixels 40 until then is performed.

In other words, an operation to eliminate the charge in the photodiode PD is performed by transmitting the charge accumulated in the photodiode PD by the photoelectric conversion to the node N1. The operation is referred to as the shutter operation, and the row for which the shutter operation is performed is referred to as the shutter row.

After the shutter operation, the charge is accumulated in the photodiode PD from which the charge is eliminated by allowing the same to receive the light again, and the video signal corresponding to a charge amount of the node N1 is read from the pixel 40 after a certain period has passed. This is referred to as the read operation. A specific operation in each configuration of the pixel 40 in the shutter operation and the read operation is to be described later.

Meanwhile, the shutter operation and the read operation are sequentially performed from a first row, and the operation in each row is controlled by the controller 9. Also, since the shutter operation is performed before the reset operation, the reset voltage is a voltage of the connection node N1 (potential of the floating diffusion). The reset voltage is reference of the potential when canceling the noise by the CDS 5.

### <Regarding FIG. 3A>

First, as illustrated in FIG. 3A, n pixels 40 arranged on the (s-7)th line and the sth line at a certain time are selected. Within the one horizontal period, the shutter operation is executed for the pixels 40 on the (s-7)th line and the read operation is executed for the pixels 40 on the sth line. That is, in this case, the pixels 40 other than the pixels 40 arranged on the sth line and the (s-7)th line do not operate. First, the shutter operation to the pixels 40 arranged on the (s-7)th line is described.

The controller 9 starts the above-described shutter operation for the n pixels 40 arranged on the (s-7)th line in the horizontal direction orthogonal to the vertical signal line VLIN.

In this manner, the charge accumulated in the photodiode PD of each of the n pixels 40 arranged on the (s-7)th line until then is emitted.

Specifically, the MOS transistor Td and the MOS transistor Tc of each of the pixels 40 on the shutter row are simultaneously turned on in a state in which the voltage VDD_{H} is supplied to the drain end of the MOS transistors Tb and Tc. In this manner, a negative charge accumulated in the photodiode PD is emitted from the floating fusion through the reset transistor (MOS transistor Tc) to a power supply line. In this manner, the photodiode PD potential becomes empty.

After that, the gate of the MOS transistor Td, which is the transistor for read of the signal charge, is turned off and the empty potential (zero potential) of the photodiode PD is fixed. Thereafter, the gate of the reset transistor (MOS transistor Tc) is turned off. This is a flow of the shutter operation.

In this manner, the shutter operation for the n pixels 40 arranged on the (s-7)th line is completed. After completing the shutter operation, the read of the charge is started in the photodiode PD in the pixels 40 arranged on the (s-7)th line after an accumulation time to be described later has passed. Thereafter, the selected row is switched and when shifting to a next (adjacent) selected row, a period is required in which the signal from the pixels on all of the rows does not appear in the vertical signal line VLIN. Therefore, the potential of the node N1 is decreased by turning on the reset transistor (MOS transistor Tc) of the selected row and the shutter row in a state in which the voltage VDD_{L} (for example, 0 V) is supplied to the drain end of the MOS transistors Tb and Tc. In this manner, the MOS transistor Tb is turned off to make the period in which the video signal is not read to the vertical signal line VLIN. Meanwhile, when the potential of the floating diffusion (N1) is fixed by turning on the reset transistor (MOS transistor Tc) in the shutter row, the potential of the floating diffusion is maintained at the fixed potential throughout a non-selected time after that. In this manner, the potential of the node N1 of all the pixels 40 on all the rows, that is, the nxm pixels 40 arranged in the matrix fashion is decreased. Therefore, the video signal is not output to the vertical signal line VLIN. Meanwhile, the operation is an operation period required in a structure in which the selection transistor is omitted from the pixel 40.

Next, the read operation for the pixels 40 arranged on the sth line is described. The n pixels 40 arranged on the sth line orthogonal to the vertical signal line VLIN receive the light again after the shutter operation. In this manner, the charge is accumulated again in the photodiode PD. Next, when a row is selected as the read row after a certain period of time has passed, the charge accumulated in the photodiode PD is read to the vertical signal line VLIN.

In this manner, in the above-described one horizontal period, the above-described read operation is started for the n pixels 40 arranged on the sth line in the horizontal direction orthogonal to the vertical signal line VLIN, and the video signal is read from the pixels 40.

### <Regarding FIG. 3B>

FIG. 3B is a conceptual diagram after seven horizontal periods have passed, for example, from the time point of FIG. 3A. Since the seven horizontal periods have passed, suppose that the shutter row moves from the (s-7)th line to the (s-14)th line. Also, suppose that the read row moves from the sth line to the (s-7)th line.

The accumulation period of the light in the photodiode PD is a period from the shutter operation to the read operation performed for the pixels 40 of interest. This is similar in all of the pixels 40.

That is, it is supposed that the period to accumulate the charge is the same in all of the pixels 40 provided in the pixel unit 4. That is, in this embodiment, in each pixel 40, the charge accumulated in the photodiode PD within the seven horizontal periods is read to the vertical signal line VLIN as the video signal.

As in the above description, within the one horizontal period, the shutter operation and the read operation are executed for the pixels 40 on the (s-14)th line and the pixels 40 on the (s-7)th line. Herein, since the shutter operation for n pixels 40 arranged on the (s-14)th line is similar to the above description, the description thereof is omitted.

Next, the read operation is performed for the n pixels 40 arranged on the (s-7)th line in the horizontal direction orthogonal to the vertical signal line VLIN. Since the read operation for the n pixels 40 arranged on the (s-7)th line is similar to the above description, the description thereof is omitted. Meanwhile, the accumulation period of the charge of the photodiode PD is a value which may be changed by the controller 9. In this manner, the rolling shutter function is a function to perform the shutter operation in the different rows at different times in a read direction, and the read operation is performed for the row in which the shutter operation is executed after the accumulation time has passed.

### <Regarding Operation of Solid State Imaging Device>

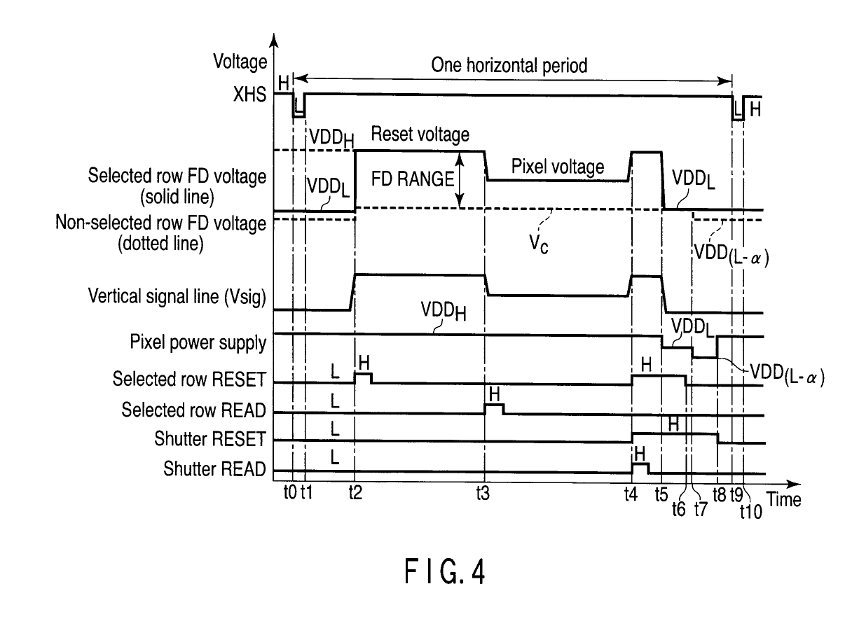

Next, an operation of each transistor provided in the pixel 40 is described with reference to FIG. 4. FIG. 4 is a time chart of a case in which the pixel 40 operates as the shutter row (shutter operation) and operates as the selected row (read operation). In this embodiment, a period from a time t0 to a time t9 is the one horizontal period.

Specifically, FIG. 4 is a time chart of the potential of the node N1 (represented as selected row FD voltage (solid line) in the drawing), the potential of the gate in the MOS transistor Tc (level of signal RESET, represented as selected row RESET in the drawing), and the potential of the gate in the MOS transistor Td (level of signal READ, represented as selected row READ in the drawing) in the pixel 40 for which the read operation is executed, the potential of the node N1 (represented as non-selected row FD voltage (dotted line) in the drawing), the potential of the gate in the MOS transistor Tc (level of signal RESET, represented as shutter RESET in the drawing), and the potential of the gate in the MOS transistor Td (level of signal RESET, represented as shutter READ in the drawing) in the pixel 40 for which the shutter operation is executed, the potential of the signal XHS, the potential of the vertical signal line VLIN (represented as vertical signal line (Vsig) in the drawing), and the potential of the pixel power supply.

The length of the one horizontal period is controlled by the signal XHS. Hereinafter, the row on which the pixels 40 for which read operation is executed are arranged is referred to as the selected row and the row on which the pixels 40 for which the shutter operation is executed are arranged is referred to as the shutter row. Although not herein illustrated, those other than the selected row and the shutter row are non-selected rows.

The above-described signal RESET and signal READ are transmitted from the controller 9 only to the pixels 40 connected to the selected row for which the read operation is executed and the shutter row for which the shutter operation is performed. That is, the above-described signal RESET and signal READ are not transmitted to other pixels 40 (connected to the non-selected rows), and the read of the video signal or the like is not executed.

<Time t0 to t1>

First, within a period from a time t0 to t1, a pulsed signal XHS (hereinafter, also referred to as an XHS pulse) set to an ‘L’ level by the controller 9 is supplied to the gate of the MOS transistor Tc. A period in which the XHS is set to the ‘L’ level is a switch timing of the row. Next, a certain row is selected when the XHS pulse is set to ‘H’, and the above-described operation is performed within the one horizontal period.

<Time t2>

As illustrated in FIG. 4, at a time t2, in the selected row, the pulsed signal RESET (hereinafter, also referred to as a RESET pulse) set to the ‘H’ level is supplied to the gate of the MOS transistor Td. Therefore, the MOS transistor Tc is turned on. Also, the potential of the pixel power supply is set to the voltage VDD_{H} before the time t0. Therefore, at the time t2, the potential of the node N1 increases from the previous voltage VDD_{L} to reach the voltage VDD_{H}. That is, the voltage VDD_{H} is applied to the gate of the MOS transistor Tb. Therefore, the MOS transistor Tb is turned on. As a result, the voltage corresponding to the potential of the node N1 is read to the vertical signal line VLIN through the MOS transistor Tb. That is, the reset voltage is read to the vertical signal line VLIN. In this manner, a voltage of the vertical signal line VLIN, that is, the vertical signal line Vsig increases. Also, a value of the vertical signal line Vsig at that time is a value decreased from the voltage VDD_{H} by a threshold of the MOS transistor Tb.

Any variation in the potential of the vertical signal line VLIN when reading the reset potential of the selected row is transmitted to the node N1 (floating diffusion) of the pixel 40 of the non-selected row including the shutter row by coupling. By this coupling, the potential of the node N1 of the pixel 40 of the non-selected row increases. As a result, the potential of the node N1 increases from the previous voltage VDD_{(L-α)} to the voltage Vc. Therefore, when reading the pixel signal at a time t3 to be described later, a dynamic range of the pixel signal in the floating diffusion of the selected row becomes narrower (potential difference between the pixel voltage and the voltage Vc within a period from t3 to t4 becomes smaller).

Thereafter, the potential of the vertical signal line VLIN is maintained at the reset potential before the signal READ pulse is applied to the pixels 40 of the selected row, and the reset potential is held in a sample hold circuit in the CDS circuit 5.

<Time t3>

Next, at the time t3, the pulsed signal READ (also referred to as the signal READ pulse) set to the ‘H’ level is applied to the pixels 40 selected as the selected row. Therefore, the MOS transistor Td is turned on. In this manner, the charge accumulated in the photodiode PD is read to the node N1. The negative charge is accumulated in the photodiode PD. In this manner, the potential of the photodiode PD gradually decreases from the potential just after the shutter is released (potential at which charge is eliminated). Therefore, the potential of the node N1 decreases from the voltage VDD_{H}. That is, the potential of the node N1 decreases from the previous voltage VDD_{H} by the potential (video signal) corresponding to the charge accumulated in the photodiode PD. The potential is the pixel voltage according to the charge accumulated in the photodiode PD, and the voltage read to the vertical signal line VLIN is a voltage obtained by subtracting the threshold of the MOS transistor Tb from the pixel voltage.

Note that the potential of the node N1 of the pixel 40 in a non-selected pixel row including the shutter row is the voltage Vc indicated by a dotted line. In a case of the pixel structure in which the selection transistor is omitted, the method of reading the pixel signal from the pixel unit which is a read target uses a characteristic in which the signal of the row in which the potential of the node N1 of the floating diffusion is the highest out of the m pixel rows is read to the vertical signal line VLIN.

Therefore, the pixel voltage cannot be equal to or lower than the potential of the node N1 of the floating diffusion of the non-selected pixel row. That is, a possible range of the potential of the node N1 of the floating diffusion of the video signal read from the pixel 40 of the selected row is a voltage between the reset voltage and the voltage Vc of the non-selected pixel row. Therefore, the dynamic range of the video signal is limited to the potential of the floating diffusion at the non-selected time.

Thereafter, the potential of the vertical signal line VLIN is maintained at the pixel voltage until a time t4 in this state, and the pixel voltage is transmitted to the CDS circuit 5 within a period from the time t3 to the time t4. Thereafter, in the CDS circuit 5, a difference between the held reset potential and the pixel voltage is obtained. By obtaining the difference, the video signal from which the fixed pattern noise due to the threshold variation of the transistor Tb and the like is removed may be obtained.

<Time t4>

Next, at the time t4, the shutter operation is executed for the pixels 40 selected as the shutter row.

That is, the signal RESET and signal READ pulse transmitted to the pixels 40 on the shutter row are simultaneously applied, and the MOS transistor Tb and the MOS transistor Tc of the pixel 40 are simultaneously turned on. In this manner, the charge accumulated in the photodiode PD of the shutter row is emitted through the pixel power supply as described above. Also, the signal RESET transmitted to the pixels 40 on the selected row is set to the ‘H’ level. Herein, the pixel power supply PXVDD is set to the voltage VDD_{H}. Therefore, the potential of the node N1 in each of the pixels 40 on the selected row and the shutter row is set to the voltage VDD_{H}. In this manner, the potential of the vertical signal line VLIN also is set to the potential lower than the voltage VDD_{H} by the threshold of the MOS transistor Tb. Thereafter, the MOS transistor Td, which is the transistor for read of the signal charge of the shutter row, is turned off to fix the empty potential (zero potential) of the photodiode PD. This is a flow of the above-described shutter operation.

<Time t5>

Next, at a time t5, a period in which the pixel signal is not read to the vertical signal line VLIN is made. Specifically, by decreasing the potential of the pixel power supply from the previous voltage VDD_{H} to the voltage VDD_{L} in a state in which the reset transistor (MOS transistor Tc) of the selected row and the shutter row are turned on, the potential of the node N1 is decreased and the MOS transistor Tb is turned off. Meanwhile, as described later at a time t8, the reset transistor (MOS transistor Tc) is turned on in the shutter row to fix the node N1 of the floating diffusion. Then, the potential of the node N1 of the floating diffusion is maintained throughout the non-selected time, so that the potential of the node N1 of all the pixels 40 on all the rows, that is, the nxm pixels 40 arranged in the matrix fashion decreases. Therefore, the pixel signal does not appear in the vertical signal line VLIN.

<Time t6>

Then, at a time t6, the gate potential to be applied to the reset transistor (MOS transistor Tc) in the selected row is decreased to the ‘L’ level (the MOS transistor Tc is in a turned off state), and the potential of the node N1 of the selected row is fixed to the voltage VDD_{L}. Therefore, after the time t5, the pixel signal is not output to the vertical signal line VLIN.

At that time, when the voltage VDD_{L} to fix the potential of the node N1 in the selected row is the voltage lower than the potential applied to the gate of the MOS transistor Td which is the transistor for read of the signal charge, the potential of the node N1 (floating diffusion) of the selected row becomes lower than the potential under the gate when the MOS transistor Td is turned off. As a result, a dark current flows from the node N1 (floating diffusion) to the photodiode PD, thereby generating the noise (appearance of a white defect). Therefore, it is necessary that the voltage VDD_{L} be set to the voltage higher than the voltage of the ‘L’ level applied to the gate of the MOS transistor Td which is the transistor for read of the signal charge.

<Time t7>

At a time t7, the potential of the pixel power supply is set to the voltage VDD_{(L-α)} lower than the above-described voltage VDD_{L} by a voltage α. Also, since the signal RESET in the shutter row maintains the ‘H’ level, the potential of the node N1 in the pixel 40 on the shutter row transits from the previous voltage Vc to the voltage VDD_{(L-α)}. Herein, the value of the voltage VDD_{(L-α)} may be set to the zero potential or the negative voltage, and the voltage VDD_{L} is required to be set to the voltage higher than the Low voltage applied to the gate of the MOS transistor Td, which is the transistor for read of the signal charge as described above.

<Time t8>

Finally, at a time t8, the pixel power supply is set to the voltage VDD_{H}. At the time t8, the signal RESET in the shutter row is set to the ‘L’ level. In this manner, the potential of the node N1 of the pixels 40 on the shutter row is fixed to the voltage VDD_{(L-α)}. Meanwhile, the voltage VDD_{(L-α)} of the node N1 fixed at the shutter time within a period from the time t7 to the time t8 is maintained at the non-selected time and thereafter.

<Time t9 to time t10>

At a time t9, the signal XHS is set to an ‘L’ level pulse from the previous ‘H’ level pulse. As described above, in a period in which the pulse is set to the ‘L’ level, the row switches to the next row. Also, as described above, the length of the one horizontal period is controlled by the signal XHS. Specifically, a period after the signal XHS is set to the ‘L’ level, then set to the ‘H’ level, and again set to the ‘L’ level is the one horizontal period. That is, as described above, within the one horizontal period, the shutter operation for the pixels 40 on the shutter row and the read operation for the pixels 40 on the selected row are executed.

<Effect according to First Embodiment>

According to the first embodiment, the solid state imaging device in which the selection transistor in a unit pixel cell is omitted can also enable the node N1 to have a large dynamic voltage range. Hereinafter, an effect in the first embodiment is described.

Since the selection transistor is omitted in the solid state imaging device according to the first embodiment, the solid state imaging device has a function of the rolling shutter. That is, before the read operation is executed for a certain pixel 40, the shutter operation is executed. That is, the potential of the node N1 of the pixel 40 for which the shutter operation is executed is set to the voltage VDD_{(L-α)}. The potential of the node N1 of the floating diffusion is maintained throughout the non-selected time. Therefore, even when the read operation is executed for another pixel, and as a result, the potential of the node N1 in the shutter row increases by the coupling together with increase in the vertical signal line VLIN, the potential of the node N1 obtained as a result of the increase is set to be lower than the voltage VDD_{L}. That is, the potential of the node N1 in the pixel 40 on the shutter row is set to the voltage Vc (<voltage VDD_{L}) (FIG. 4).

Therefore, the possible dynamic range of the video signal read to the pixel 40 on the selected row is the voltage between the reset voltage and the voltage Vc of the non-selected pixel row. Conventionally, the potential of the node N1 of the pixel 40 for which the shutter operation is executed is a value higher than the zero potential, so that the value of the voltage VC also increases. That is, it is not possible to have a sufficient dynamic range.

However, with the solid state imaging device and the method of controlling the same according to the first embodiment, since the value of the voltage Vc may be made smaller as described above, it is possible to have the sufficient dynamic range of the potential of the node N1 in the pixel 40 on the selected row. That is, it is possible to have a large range of the output potential of the video signal, so that even when the video is especially bright, that is, when a subject whose light is received by the lens 10 is of a high light intensity, that is, with a high signal, the subject may be truly reproduced.

### Second Embodiment

Next, a solid state imaging device and a method of controlling the same according to a second embodiment are described. The solid state imaging device and the method of controlling the same according to the second embodiment are configured to divide a signal RESET transmitted to the shutter row into two pulses in the solid state imaging device and the method of controlling the same according to the first embodiment. Since the configuration thereof is identical to that of the solid state imaging device according to the first embodiment, the description thereof is omitted.

### <Regarding Operation of Pixel 40>

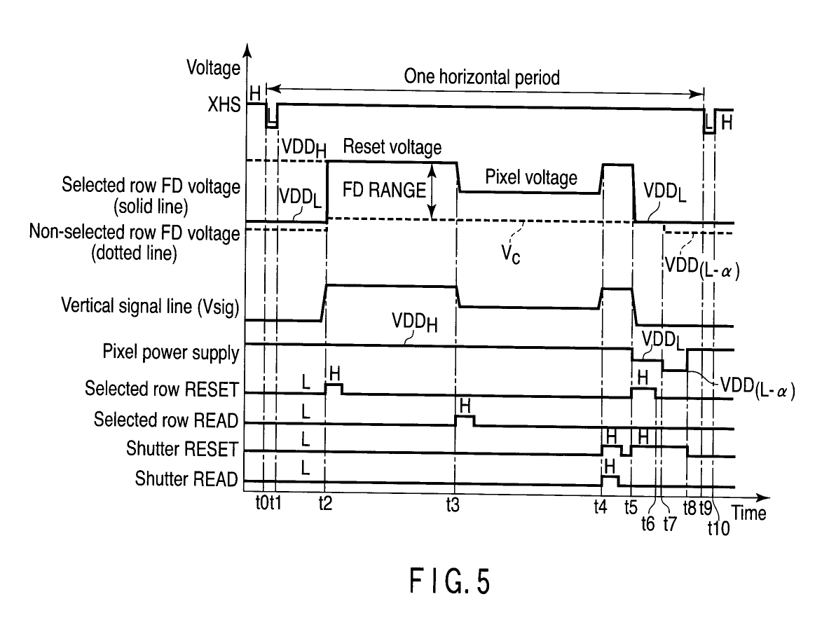

Next, an operation of each transistor in the pixel 40 is described with reference to FIG. 5. FIG. 5 is a time chart illustrating the operation of each transistor when the pixel 40 operates as the shutter row (shutter operation) and as the selected row (read operation). In this embodiment also, the period from the time t0 to the time t9 is the one horizontal period.

Specifically, FIG. 5 is the time chart of the potential of the node N1 (represented as selected row FD voltage (solid line) in the drawing), the potential of the gate in the MOS transistor Tc (level of signal RESET, represented as selected row RESET in the drawing), and the potential of the gate in the MOS transistor Td (level of signal READ, represented as selected row READ in the drawing) in the pixel 40 for which the read operation is executed, the potential of the node N1 (represented as non-selected row FD voltage (dotted line) in the drawing), and the potential of the gate in the MOS transistor Tc (level of signal RESET, represented as shutter RESET in the drawing), the potential of the gate in the MOS transistor Td (level of signal RESET, represented as shutter READ in the drawing) of the pixel 40 for which the shutter operation is executed, the potential of the signal XHS, the potential of the vertical signal line VLIN (represented as vertical signal line (Vsig) in the drawing), and the potential of the pixel power supply.

Also, the period from the time t0 to the time t9 is the one horizontal period in this embodiment and the length of the one horizontal period is controlled by the signal XHS. Hereinafter, the row on which the pixels 40 for which the read operation is executed are arranged is referred to as the selected row and the row on which the pixels 40 for which the shutter operation is executed are arranged is referred to as the shutter row, as in the first embodiment.

The above-described signal RESET and signal READ are transmitted only to the pixels 40 connected to the selected row for which the read operation is executed and the shutter row for which the shutter operation is performed. That is, the above-described signal RESET and signal READ are not transmitted to other pixels 40 (connected to the non-selected rows) and the read of the video signal or the like is not executed. The description of an operation identical to that in FIG. 4 is omitted.

<Time t4>

At the time t4, the signal RESET and the signal READ pulse transmitted to the pixel 40 on the shutter row are simultaneously applied, and the MOS transistor Td and the MOS transistor Tc of the pixel 40 are turned on simultaneously. In this manner, the charge of the photodiode PD is eliminated. Thereafter, the MOS transistor Td, which is the transistor for read of the signal charge, is turned off to fix the empty potential (zero potential) of the photodiode PD. The accumulation of the charge is started from the time point of the empty potential. This is the shutter operation. Thereafter, the reset transistor (MOS transistor Tc) is turned off once.

Meanwhile, it is only necessary to reset the photodiode PD potential of the shutter row at the time t4. Therefore, at the time t4, the pulse is applied only to the shutter row and the signal RESET is not supplied to the selected row in the second embodiment. The reset operation of the potential of the photodiode PD at the time t4 is different from the operation in which the video signal does not appear in the vertical signal line VLIN at the next time t5. Therefore, the signal RESET is transmitted twice to the pixel 40 which is set as the shutter row at the time t4 and the time t5.

<Time t5>

The signal RESET transmitted to the pixel 40 on the shutter row is again set to the ‘H’ level at the time t5. In a state in which the ‘H’ level is applied to the gate of the reset transistor (MOS transistor Tc) of the selected row and the shutter row, the potential of the pixel power supply is decreased from the previous voltage VDD_{H} to the voltage VDD_{L}. Next, the potential of the node N1 is decreased to turn off the MOS transistor Tb and makes the period in which the video signal is not read to the vertical signal line VLIN. Meanwhile, when the potential of the node N1 of the floating diffusion of the reset transistor (MOS transistor Tc) is fixed in the shutter row, the node N1 potential of the floating diffusion is maintained throughout the non-selected time. The remaining configuration is similar to that of the first embodiment, thus description thereof is omitted.

### <Effect According to Second Embodiment>

With the solid state imaging device and the method of controlling the same according to the second embodiment also, the effect similar to that of the first embodiment may be obtained.

That is, even when the signal of the ‘H’ level of the signal RESET transmitted to the pixel 40 on the shutter row at the time t4 is transmitted twice, the effect may be obtained as in the first embodiment. In other words, with the solid state imaging device and the method of controlling the same according to the second embodiment, it is possible to have the sufficient dynamic range of the potential at the node N1 and even with the subject with a lot of signals, the video may be truly reproduced as in the first embodiment.

Meanwhile, although the signal RESET in the selected row is set to the ‘L’ level at the time t6 in the first and second embodiments, it may be set at the ‘H’ level also after the time t6. That is, the potential of the node N1 of the pixel 40 on the selected row may also be the voltage VDD_{(L-α)}.

Therefore, the signal RESET in the selected row in FIGS. 4 and 5 may be at the ‘H’ level until the time t8.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid state imaging device comprising:
a photodiode which performs photoelectric conversion of received light and accumulates a charge obtained by the photoelectric conversion;
a first transistor which reads the charge accumulated in the photodiode;
a floating diffusion which is one end of a current pathway of the first transistor, and the charge of which is read through the first transistor;
a second transistor whose gate is connected to the floating diffusion and in which one end of a current pathway is connected to a vertical signal line; and
a third transistor in which one end of a current pathway is connected to the floating diffusion and another end is connected to a power supply, the charge accumulated in the floating diffusion being discharged to the power supply by turning on the third transistor.

2. The device according to claim 1, further comprising:
a voltage generating circuit which generates a first voltage, a second voltage, and a third voltage, the voltage generating circuit transferring the first, second and third voltages to the floating diffusion by way of the third transistor; and
a controller which controls a timing to output the first, second, and third voltages to the floating diffusion,
wherein each of a plurality of pixels includes the photodiode, the first transistor, the floating diffusion, the second transistor and the third transistor, and
the controller controls a potential of the floating diffusion of each of the pixels.

3. The device according to claim 2, wherein:
after the controller turns on the third transistor and applies a pixel resetting potential to the vertical signal line by way of the floating diffusion,
the controller turns on the first transistor, thereby attaining a rolling shutter function by which the charge accumulated in the photodiode for a predetermined period is read and supplied to the floating diffusion.

4. The device according to claim 2, wherein the voltage generating circuit includes:
a positive boosted voltage generator which generates the first voltage and the second voltage; and
a negative boosted voltage generator which generates either a negative voltage or a zero potential as the third voltage,
wherein the controller
controls a timing to output the first, second and third voltages from the vertical signal line,
allows the negative boosted voltage generator to serve as a negative voltage generator when the third voltage is set as the negative voltage, and
grounds the vertical signal line when the third voltage is set as a zero voltage.

5. The device according to claim 2, wherein the third voltage is either a zero potential or a negative potential.

6. A solid state imaging device comprising:
a plurality of effective pixels arranged in a row direction and in a column direction, the effective pixels including a first pixel which is set as a selected row for outputting a charge, a second pixel which is set as a shutter row for starting accumulation in the first pixel, and the other pixels, each of the first pixel, the second pixel and the other pixels including: a first photodiode; a first transistor which reads the charge accumulated in the first photodiode; a floating diffusion which is one end of a current pathway of the first transistor, and the charge of which is read through the first transistor; a second transistor whose gate is connected to the floating diffusion and in which one end of a current pathway is connected to a vertical signal line; and a third transistor in which one end of a current pathway is connected to the floating diffusion section and another end is connected to a power supply; and
a vertical signal line extending in the column direction and connected in common to the first pixel, the second pixel, and the other pixels,
wherein the power supply controls a potential of the floating diffusion of the second pixel when a shutter operation as starting accumulation, when no charge is output from the first pixel to the vertical signal line.

7. The device according to claim 6, wherein the floating diffusion of the first pixel set as the selected row has a voltage range determined by a resetting potential of the floating diffusion of the first pixel and a potential of the floating diffusion of the second pixel, the resetting potential being a reference potential of a pixel voltage read from the photodiode.

8. The device according to claim 7, further comprising:
a voltage generating circuit which generates a first voltage, a second voltage and a third voltage, which are to be output to the vertical signal line and the floating diffusion section; and
a controller which controls a timing to output the first, second and third voltages to the floating diffusion section of the second pixel set as the shutter row.

9. The device according to claim 8, wherein the third voltage is either a negative voltage or a zero potential, and
the controller grounds the vertical signal line when the third voltage is set at the zero potential.

10. The device according to claim 8, wherein:
a potential of the floating diffusion of the second pixel is set at the third voltage when the third transistor is turned on;
a potential of the floating diffusion of the second pixel increases from the third voltage through the vertical signal line, when the potential of the floating diffusion section of the first pixel is increased by the third transistor set in an on state; and
the floating diffusion of the selected row has an output voltage range determined by a potential difference between a potential of the floating diffusion of the second pixel and the resetting potential of the floating diffusion of the first pixel.

11. The device according to claim 8, wherein:
the third transistor of the first pixel is turned on to set the potential of the floating diffusion at the second voltage, after the pixel signal is read from the first pixel and supplied to the vertical signal line; and
the third transistor of the second pixel is turned on to set the potential of the floating diffusion of the second pixel at the third voltage, after the third transistor of the first pixel is turned off.

12. A method of controlling a solid state imaging device, the method comprising:
allowing a floating diffusion of a selected row included in a first pixel unit to transition from a first potential, used as a reference of a video signal, to a potential corresponding to a charge accumulated in a photodiode;
setting the floating diffusion of the selected row from the potential to a second voltage, and simultaneously setting the floating diffusion of a shutter at the second voltage; and
setting the floating diffusion of the non-selected row from the second voltage to a third voltage below the second voltage, while simultaneously keeping the potential of the floating diffusion at the second voltage, the floating diffusion of the non-selected row being held at the third voltage until a read operation for a next selected row is performed.

13. The method according to claim 12, wherein third transistors in select row and shutter row are turned on simultaneously to set both the floating diffusion of the selected row and the floating diffusion of the non-selected row at the second voltage, and
after the third transistor of as select row is turned off, set the potential of the floating diffusion from second voltage to third voltage, the third transistor set as shutter row is turned off.

14. The method according to claim 13, wherein the third voltage is either a negative voltage or a zero potential.

15. The method according to claim 14, further comprising:
generating the first voltage, the second voltage, and the third voltages by a voltage generating circuit;
allowing the voltage generating circuit to serve as a negative voltage generating circuit when the negative voltage is transmitted to the floating diffusion as the zero potential; and
grounding the floating diffusion by the voltage generating circuit when the zero potential is transmitted to the floating diffusion as the third voltage.

16. The method according to claim 12, wherein a video signal accumulated in a first video section is read by:
increasing the floating diffusion of the selected row from the second voltage to the first voltage, with the floating diffusion of the non-selected row being kept at the third voltage;
turning on the third transistor of select row, and outputting a voltage of the floating diffusion corresponding to a potential of a reset signal to a signal line;
turning on the first transistor of select row, and outputting the video signal from the first pixel unit to the signal line through the floating diffusion.
